(19) United States
(12) Patent Application Publication
(10) Pub. No.: US 2024/0387490 A1
(43) Pub. Date: Nov. 21, 2024

(54) DISPLAY DEVICE USING SEMICONDUCTOR LIGHT EMITTING DEVICE AND METHOD FOR MANUFACTURING THE SAME

(71) Applicant: LG ELECTRONICS INC., Seoul (KR)

(72) Inventors: Byoungkwon CHO, Seoul (KR); Hongcheol LEE, Seoul (KR); Wonseok CHOI, Seoul (KR)

(73) Assignee: LG ELECTRONICS INC., Seoul (KR)

(21) Appl. No.: 18/443,406

(22) Filed: Feb. 16, 2024

(30) Foreign Application Priority Data
May 17, 2023 (KR) 10-2023-0063888

(51) Int. Cl. H01L 25/16; H01L 33/54; H01L 33/56

(52) U.S. Cl. CPC H01L 25/167; H01L 33/54; H01L 33/56

(57) ABSTRACT

The present disclosure is applicable to a display device-related technology field, for example, relates to a display device using a micro light emitting diode (LED) and a method for manufacturing the same. The display device using the semiconductor light emitting device includes a wiring substrate with a first electrode disposed thereon, a light emitting device disposed on the wiring substrate to constitute a unit sub-pixel, a seating layer located between the wiring substrate and the light emitting device, wherein the seating layer includes a first portion in contact with the light emitting device and a second portion located under the first portion and having an area size greater than an area size of the first portion, a first connection electrode electrically connecting the first electrode to one side of the light emitting device corresponding to a shape of the seating layer, a planarization layer covering the light emitting device and the first connection electrode, and a second connection electrode located on the planarization layer and electrically connected to the other side of the light emitting device.

This application claims the benefit of Korean Patent Application No. 10-2023-0063888 filed on May 17, 2023, which is hereby incorporated by reference as if fully set forth herein.

### BACKGROUND

### Field

The present disclosure is applicable to a display device-related technology field, and, for example, relates to a display device using a micro light emitting diode (LED) and a method for manufacturing the same.

### Discussion of the Related Art

Recently, in a field of a display technology, display devices having excellent characteristics such as thinness, flexibility, and the like have been developed. On the other hand, currently commercialized major displays are represented by a LCD (liquid crystal display) and an OLED (organic light emitting diode).

On the other hand, LED (light emitting diode), which is a well-known semiconductor light-emitting element that converts electric current into light, has been used as a light source for a display image of an electronic device including an information and communication device along with a GaP:N-based green LED, starting with commercialization of a red LED using a GaAsP compound semiconductor in 1962. Accordingly, a method for solving the above-described problems by implementing a display using the semiconductor light-emitting element may be proposed.

Recently, such light emitting diode (LED) has been gradually miniaturized and manufactured into a micro-sized LED to be used as a pixel of the display device.

Such micro LED technology exhibits characteristics of low power, high brightness, and high reliability compared to other display devices/panels, and is able to be applied to a flexible device as well. Therefore, in recent years, research institutes and companies have been actively researching the micro LED.

A recent issue in relation to the micro LED is a technology to transfer the LED to a panel. Many LEDs are used to manufacture one display device using the micro LEDs, but it is very difficult and time-consuming to manufacture the display device by attaching the LEDs to the panel one by one.

After the micro LED is transferred to a wiring substrate, the micro LED must be electrically connected to an electrode partitioned on the wiring substrate.

In the process of transferring the LED to the wiring substrate, the LED may be transferred by being attached to an adhesive layer located on the wiring substrate. In this regard, the adhesive layer has the same area size as a bottom surface of the LED.

In this case, in the process of forming a connection electrode that connects the LED to the electrode partitioned on the wiring electrode, an undercut may occur at a portion where the adhesive layer is connected to the LED, causing the connection electrode to be disconnected.

When the connection electrode is formed to have a great thickness, it is difficult to adjust an ashing process for patterning the connection electrode. Then, a metal on a side surface of the LED may be etched and the connecting electrode may be disconnected.

Therefore, a method to solve such problem is required.

### SUMMARY

One embodiment of the present disclosure is to provide a display device using a semiconductor light emitting device and a method for manufacturing the same in which a connection electrode may be stably connected to and located between the light emitting device and a wiring electrode.

In addition, it is to provide a display device using a semiconductor light emitting device and a method for manufacturing the same in which a connection electrode may be disposed stably as a step of an adhesive layer supporting the light emitting device is reduced.

In addition, it is to provide a display device using a semiconductor light emitting device and a method for manufacturing the same that may reduce a thickness of a metal deposited for a connection electrode, and thus, may reduce an etching time of the metal and a manufacturing time.

Furthermore, the purpose of one embodiment of the present disclosure is to solve various problems not mentioned herein. Those skilled in the art may understand this through the entire purpose of the present disclosure and drawings.

A first aspect of the present disclosure provides a display device using a semiconductor light emitting device including a wiring substrate with a first electrode disposed thereon, a light emitting device disposed on the wiring substrate to constitute a unit sub-pixel, a seating layer located between the wiring substrate and the light emitting device, wherein the seating layer includes a first portion in contact with the light emitting device and a second portion located under the first portion and having an area size greater than an area size of the first portion, a first connection electrode electrically connecting the first electrode to one side of the light emitting device corresponding to a shape of the seating layer, a planarization layer covering the light emitting device and the first connection electrode, and a second connection electrode located on the planarization layer and electrically connected to the other side of the light emitting device.

In one implementation, the first portion and the second portion may form a staircase shape.

In one implementation, the area size of the first portion may be equal to an area size of a bottom surface of the light emitting device.

In one implementation, the seating layer may further include a third portion connecting the first portion and the second portion to each other with a gentle slope.

In one implementation, the light emitting device may be located on a center of the second portion.

In one implementation, the one side of the light emitting device connected with the first connection electrode may be a side surface of a light emitting layer of the light emitting device.

In one implementation, the first connection electrode may connect the first electrode with a lower portion of the side surface of the light emitting layer of the light emitting device.

In one implementation, a passivation layer may be located on an outer side of the light emitting device, and the first connection electrode may be located beneath the passivation layer.

In one implementation, the first connection electrode may be connected to the first electrode at an end of the second portion of the seating layer.

In one implementation, the first connection electrode may be connected to a lower electrode of the light emitting device.

In one implementation, the second connection electrode may include a transparent electrode.

In one implementation, the display device may further include a second electrode connected to the second connection electrode.

In one implementation, the seating layer may include a cured resin layer.

A second aspect of the preset disclosure provides a display device using a semiconductor light emitting device including a wiring substrate with a first electrode disposed thereon, a light emitting device disposed on the wiring substrate, a seating layer located between the wiring substrate and the light emitting device, supporting a first surface of the light emitting device, and having an area size greater than an area size of the first surface, a first connection electrode electrically connecting the first electrode to one side of the light emitting device, a planarization layer covering the light emitting device and the first connection electrode, and a second connection electrode located on the planarization layer and electrically connected to the other side of the light emitting device.

A third aspect of the preset disclosure provides a method for manufacturing a display device using a semiconductor light emitting device including seating the light emitting device on a wiring substrate having an adhesive layer and a first electrode such that a first surface of the light emitting device is in contact with the adhesive layer, etching the adhesive layer in a depth direction of the wiring substrate, forming a first connection electrode connecting one side of the light emitting device to the first electrode along a top surface of the adhesive layer, forming a planarization layer covering the light emitting device and the first connection electrode, and forming a second connection electrode electrically connected to the other side of the light emitting device on the planarization layer.

In one implementation, the etching of the adhesive layer may include etching the adhesive layer such that the adhesive layer includes a first portion in contact with the light emitting device and a second portion located under the first portion and having an area size greater than an area size of the first portion.

In one implementation, the forming of the first connection electrode may include etching a portion of the adhesive layer to open a portion of the first connection electrode to define an exposed portion.

According to one embodiment of the present disclosure, the connection electrode may be stably connected to and located between the light emitting device and the wiring electrode, thereby lowering the defect rate in the lighting process.

According to the embodiment of the present disclosure, the step of the adhesive layer supporting the light emitting device may be reduced step by step, so that the connection electrode may be formed stably.

According to the embodiment of the present disclosure, the thickness of the metal deposited for the connection electrode may be reduced. Accordingly, the etching time of the metal may be reduced.

Furthermore, according to one embodiment of the present disclosure, there are additional technical effects not mentioned herein. Those skilled in the art may understand this through the entire purpose of the present disclosure and drawings.

### BRIEF DESCRIPTION OF THE DRAWINGS

FIG. 1 is a conceptual diagram illustrating an embodiment of a display device using a semiconductor light emitting device according to the present disclosure;

FIG. 2 is a partially enlarged diagram showing a part A shown in FIG. 1.

FIGS. 3A and 3B are cross-sectional diagrams taken along the cutting lines B-B and C-C in FIG. 2;

FIG. 4 is a conceptual diagram illustrating the flip-chip type semiconductor light emitting device of FIG. 3;

FIGS. 5A to 5C are conceptual diagrams illustrating various examples of color implementation with respect to a flip-chip type semiconductor light emitting device;

FIG. 6 shows cross-sectional views of a method of fabricating a display device using a semiconductor light emitting device according to the present disclosure;

FIG. 7 is a perspective diagram of a display device using a semiconductor light emitting device according to another embodiment of the present disclosure;

FIG. 8 is a cross-sectional diagram taken along a cutting line D-D shown in FIG. 7;

FIG. 9 is a conceptual diagram showing a vertical type semiconductor light emitting device shown in FIG. 8;

FIG. 10 is a cross-sectional view showing a display device using a semiconductor light emitting device according to an embodiment of the present disclosure;

FIG. 11A is a cross-sectional view showing an individual sub-pixel of a display device using a semiconductor light emitting device according to an embodiment of the present disclosure;

FIG. 11B is a cross-sectional view showing an individual sub-pixel of a display device using a semiconductor light emitting device according to another embodiment of the present disclosure;

FIG. 12 is a plan view showing an individual sub-pixel of a display device using a semiconductor light emitting device according to an embodiment of the present disclosure;

FIGS. 13 to 30 are cross-sectional views showing a process of manufacturing a display device using a semiconductor light emitting device according to an embodiment of the present disclosure;

FIG. 31 is a cross-sectional view showing a display device using a semiconductor light emitting device according to a comparative example;

FIG. 32 is a photograph showing a portion of a display device using a semiconductor light emitting device according to a comparative example;

FIG. 33 is an enlarged photograph of a portion A in FIG. 32;

FIG. 34 is a photograph showing a portion of a display device using a semiconductor light emitting device according to an embodiment of the present disclosure; and

FIG. 35 is an enlarged photograph of a portion C in FIG. 34.

### DESCRIPTION OF SPECIFIC EMBODIMENTS

Reference will now be made in detail to embodiments of the present disclosure, examples of which are illustrated in the accompanying drawings. Wherever possible, the same reference numbers will be used throughout the drawings to refer to the same or like parts, and redundant description thereof will be omitted. As used herein, the suffixes “module” and “unit” are added or used interchangeably to facilitate preparation of this specification and are not intended to suggest distinct meanings or functions. In describing embodiments disclosed in this specification, relevant well-known technologies may not be described in detail in order not to obscure the subject matter of the embodiments disclosed in this specification. In addition, it should be noted that the accompanying drawings are only for easy understanding of the embodiments disclosed in the present specification, and should not be construed as limiting the technical spirit disclosed in the present specification.

Furthermore, although the drawings are separately described for simplicity, embodiments implemented by combining at least two or more drawings are also within the scope of the present disclosure.

In addition, when an element such as a layer, region or module is described as being “on” another element, it is to be understood that the element may be directly on the other element or there may be an intermediate element between them.

The display device described herein is a concept including all display devices that display information with a unit pixel or a set of unit pixels. Therefore, the display device may be applied not only to finished products but also to parts. For example, a panel corresponding to a part of a digital TV also independently corresponds to the display device in the present specification. The finished products include a mobile phone, a smartphone, a laptop, a digital broadcasting terminal, a personal digital assistant (PDA), a portable multimedia player (PMP), a navigation system, a slate PC, a tablet, an Ultrabook, a digital TV, a desktop computer, and the like.

However, it will be readily apparent to those skilled in the art that the configuration according to the embodiments described herein is applicable even to a new product that will be developed later as a display device.

In addition, the semiconductor light emitting device mentioned in this specification is a concept including an LED, a micro LED, and the like, which may be used in a mixed manner.

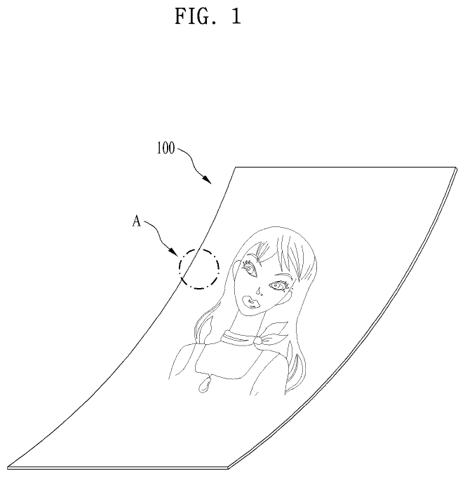

FIG. 1 is a conceptual view illustrating an embodiment of a display device using a semiconductor light emitting device according to the present disclosure.

As shown in FIG. 1, information processed by a controller (not shown) of a display device 100 may be displayed using a flexible display.

The flexible display may include, for example, a display that can be warped, bent, twisted, folded, or rolled by external force.

Furthermore, the flexible display may be, for example, a display manufactured on a thin and flexible substrate that can be warped, bent, folded, or rolled like paper while maintaining the display characteristics of a conventional flat panel display.

When the flexible display remains in an unbent state (e.g., a state having an infinite radius of curvature) (hereinafter referred to as a first state), the display area of the flexible display forms a flat surface. When the display in the first state is changed to a bent state (e.g., a state having a finite radius of curvature) (hereinafter referred to as a second state) by external force, the display area may be a curved surface. As shown in FIG. 1, the information displayed in the second state may be visual information output on a curved surface. Such visual information may be implemented by independently controlling the light emission of sub-pixels arranged in a matrix form. The unit pixel may mean, for example, a minimum unit for implementing one color.

The unit pixel of the flexible display may be implemented by a semiconductor light emitting device. In the present disclosure, a light emitting diode (LED) is exemplified as a type of the semiconductor light emitting device configured to convert electric current into light. The LED may be formed in a small size, and may thus serve as a unit pixel even in the second state.

Hereinafter, a flexible display implemented using the LED will be described in more detail with reference to the drawings.

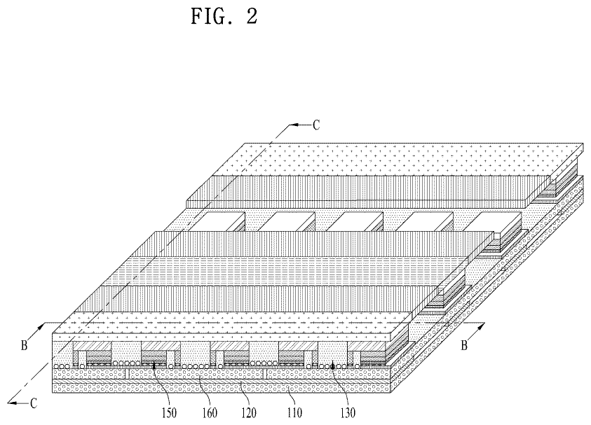

FIG. 2 is a partially enlarged view showing part A of FIG. 1.

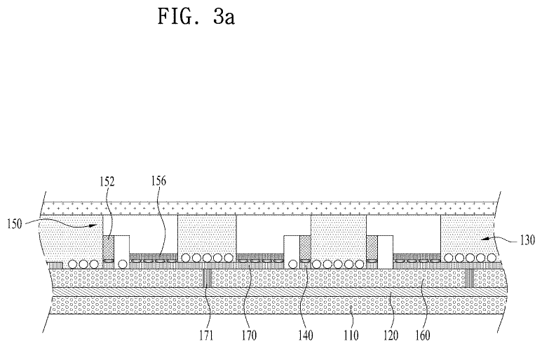

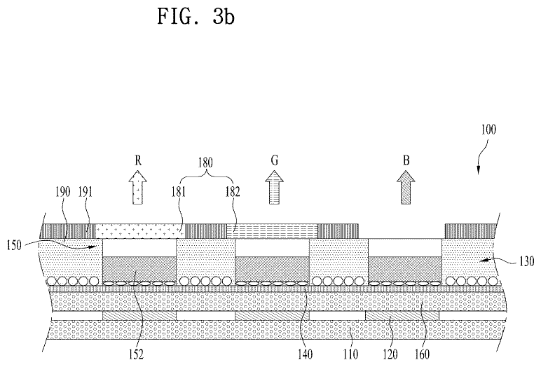

FIGS. 3A and 3B are cross-sectional views taken along lines B-B and C-C in FIG. 2.

As shown in FIGS. 2, 3A and 3B, the display device 100 using a passive matrix (PM) type semiconductor light emitting device is exemplified as the display device 100 using a semiconductor light emitting device. However, the examples described below are also applicable to an active matrix (AM) type semiconductor light emitting device.

The display device 100 shown in FIG. 1 may include a substrate 110, a first electrode 120, a conductive adhesive layer 130, a second electrode 140, and at least one semiconductor light emitting device 150, as shown in FIG. 2.

The substrate 110 may be a flexible substrate. For example, to implement a flexible display device, the substrate 110 may include glass or polyimide (PI). Any insulative and flexible material such as polyethylene naphthalate (PEN) or polyethylene terephthalate (PET) may be employed. In addition, the substrate 110 may be formed of either a transparent material or an opaque material.

The substrate 110 may be a wiring substrate on which the first electrode 120 is disposed. Thus, the first electrode 120 may be positioned on the substrate 110.

As shown in FIG. 3A, an insulating layer 160 may be disposed on the substrate 110 on which the first electrode 120 is positioned, and an auxiliary electrode 170 may be positioned on the insulating layer 160. In this case, a stack in which the insulating layer 160 is laminated on the substrate 110 may be a single wiring substrate. More specifically, the insulating layer 160 may be formed of an insulative and flexible material such as PI, PET, or PEN, and may be integrated with the substrate 110 to form a single substrate.

The auxiliary electrode 170, which is an electrode that electrically connects the first electrode 120 and the semiconductor light emitting device 150, is positioned on the insulating layer 160, and is disposed to correspond to the position of the first electrode 120. For example, the auxiliary electrode 170 may have a dot shape and may be electrically connected to the first electrode 120 by an electrode hole 171 formed through the insulating layer 160. The electrode hole 171 may be formed by filling a via hole with a conductive material.

As shown in FIG. 2 or 3A, a conductive adhesive layer 130 may be formed on one surface of the insulating layer 160, but embodiments of the present disclosure are not limited thereto. For example, a layer performing a specific function may be formed between the insulating layer 160 and the conductive adhesive layer 130, or the conductive adhesive layer 130 may be disposed on the substrate 110 without the insulating layer 160. In a structure in which the conductive adhesive layer 130 is disposed on the substrate 110, the conductive adhesive layer 130 may serve as an insulating layer.

The conductive adhesive layer 130 may be a layer having adhesiveness and conductivity. For this purpose, a material having conductivity and a material having adhesiveness may be mixed in the conductive adhesive layer 130. In addition, the conductive adhesive layer 130 may have ductility, thereby providing making the display device flexible.

As an example, the conductive adhesive layer 130 may be an anisotropic conductive film (ACF), an anisotropic conductive paste, a solution containing conductive particles, or the like. The conductive adhesive layer 130 may be configured as a layer that allows electrical interconnection in the direction of the Z-axis extending through the thickness, but is electrically insulative in the horizontal X-Y direction. Accordingly, the conductive adhesive layer 130 may be referred to as a Z-axis conductive layer (hereinafter, referred to simply as a “conductive adhesive layer”).

The ACF is a film in which an anisotropic conductive medium is mixed with an insulating base member. When the ACF is subjected to heat and pressure, only a specific portion thereof becomes conductive by the anisotropic conductive medium. Hereinafter, it will be described that heat and pressure are applied to the ACF. However, another method may be used to make the ACF partially conductive. The other method may be, for example, application of only one of the heat and pressure or UV curing.

In addition, the anisotropic conductive medium may be, for example, conductive balls or conductive particles. For example, the ACF may be a film in which conductive balls are mixed with an insulating base member. Thus, when heat and pressure are applied to the ACF, only a specific portion of the ACF is allowed to be conductive by the conductive balls. The ACF may contain a plurality of particles formed by coating the core of a conductive material with an insulating film made of a polymer material. In this case, as the insulating film is destroyed in a portion to which heat and pressure are applied, the portion is made to be conductive by the core. At this time, the cores may be deformed to form layers that contact each other in the thickness direction of the film. As a more specific example, heat and pressure are applied to the whole ACF, and an electrical connection in the Z-axis direction is partially formed by the height difference of a counterpart adhered by the ACF.

As another example, the ACF may contain a plurality of particles formed by coating an insulating core with a conductive material. In this case, as the conductive material is deformed (pressed) in a portion to which heat and pressure are applied, the portion is made to be conductive in the thickness direction of the film. As another example, the conductive material may be disposed through the insulating base member in the Z-axis direction to provide conductivity in the thickness direction of the film. In this case, the conductive material may have a pointed end.

The ACF may be a fixed array ACF in which conductive balls are inserted into one surface of the insulating base member. More specifically, the insulating base member may be formed of an adhesive material, and the conductive balls may be intensively disposed on the bottom portion of the insulating base member. Thus, when the base member is subjected to heat and pressure, it may be deformed together with the conductive balls, exhibiting conductivity in the vertical direction.

However, the present disclosure is not necessarily limited thereto, and the ACF may be formed by randomly mixing conductive balls in the insulating base member, or may be composed of a plurality of layers with conductive balls arranged on one of the layers (as a double-ACF).

The anisotropic conductive paste may be a combination of a paste and conductive balls, and may be a paste in which conductive balls are mixed with an insulating and adhesive base material. Also, the solution containing conductive particles may be a solution containing any conductive particles or nanoparticles.

Referring back to FIG. 3A, the second electrode 140 is positioned on the insulating layer 160 and spaced apart from the auxiliary electrode 170. That is, the conductive adhesive layer 130 is disposed on the insulating layer 160 having the auxiliary electrode 170 and the second electrode 140 positioned thereon.

After the conductive adhesive layer 130 is formed with the auxiliary electrode 170 and the second electrode 140 positioned on the insulating layer 160, the semiconductor light emitting device 150 is connected thereto in a flip-chip form by applying heat and pressure. Thereby, the semiconductor light emitting device 150 is electrically connected to the first electrode 120 and the second electrode 140.

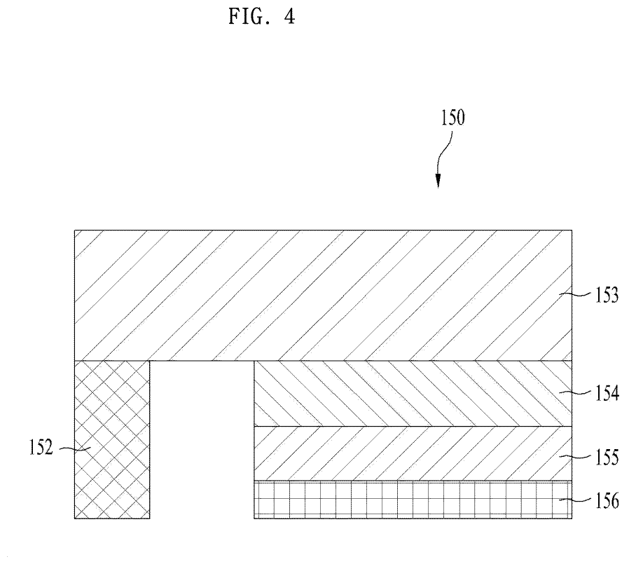

FIG. 4 is a conceptual view illustrating the flip-chip type semiconductor light emitting device of FIG. 3.

Referring to FIG. 4, the semiconductor light emitting device may be a flip chip-type light emitting device.

For example, the semiconductor light emitting device may include a p-type electrode 156, a p-type semiconductor layer 155 on which the p-type electrode 156 is formed, an active layer 154 formed on the p-type semiconductor layer 155, an n-type semiconductor layer 153 formed on the active layer 154, and an n-type electrode 152 disposed on the n-type semiconductor layer 153 and horizontally spaced apart from the p-type electrode 156. In this case, the p-type electrode 156 may be electrically connected to the auxiliary electrode 170, which is shown in FIG. 3, by the conductive adhesive layer 130, and the n-type electrode 152 may be electrically connected to the second electrode 140.

Referring back to FIGS. 2, 3A and 3B, the auxiliary electrode 170 may be elongated in one direction. Thus, one auxiliary electrode may be electrically connected to the plurality of semiconductor light emitting devices 150. For example, p-type electrodes of semiconductor light emitting devices on left and right sides of an auxiliary electrode may be electrically connected to one auxiliary electrode.

More specifically, the semiconductor light emitting device 150 may be press-fitted into the conductive adhesive layer 130 by heat and pressure. Thereby, only the portions of the semiconductor light emitting device 150 between the p-type electrode 156 and the auxiliary electrode 170 and between the n-type electrode 152 and the second electrode 140 may exhibit conductivity, and the other portions of the semiconductor light emitting device 150 do not exhibit conductivity as they are not press-fitted. In this way, the conductive adhesive layer 130 interconnects and electrically connects the semiconductor light emitting device 150 and the auxiliary electrode 170 and interconnects and electrically connects the semiconductor light emitting device 150 and the second electrode 140.

The plurality of semiconductor light emitting devices 150 may constitute a light emitting device array, and a phosphor conversion layer 180 may be formed on the light emitting device array.

The light emitting device array may include a plurality of semiconductor light emitting devices having different luminance values. Each semiconductor light emitting device 150 may constitute a unit pixel and may be electrically connected to the first electrode 120. For example, a plurality of first electrodes 120 may be provided, and the semiconductor light emitting devices may be arranged in, for example, several columns. The semiconductor light emitting devices in each column may be electrically connected to any one of the plurality of first electrodes.

In addition, since the semiconductor light emitting devices are connected in a flip-chip form, semiconductor light emitting devices grown on a transparent dielectric substrate may be used. The semiconductor light emitting devices may be, for example, nitride semiconductor light emitting devices. Since the semiconductor light emitting device 150 has excellent luminance, it may constitute an individual unit pixel even when it has a small size.

As shown in FIGS. 3a and 3b, a partition wall 190 may be formed between the semiconductor light emitting devices 150. In this case, the partition wall 190 may serve to separate individual unit pixels from each other, and may be integrated with the conductive adhesive layer 130. For example, by inserting the semiconductor light emitting device 150 into the ACF, the base member of the ACF may form the partition wall.

In addition, when the base member of the ACF is black, the partition wall 190 may have reflectance and increase contrast even without a separate black insulator.

As another example, a reflective partition wall may be separately provided as the partition wall 190. In this case, the partition wall 190 may include a black or white insulator depending on the purpose of the display device. When a partition wall including a white insulator is used, reflectivity may be increased. When a partition wall including a black insulator is used, it may have reflectance and increase contrast.

The phosphor conversion layer 180 may be positioned on the outer surface of the semiconductor light emitting device 150. For example, the semiconductor light emitting device 150 may be a blue semiconductor light emitting device that emits blue (B) light, and the phosphor conversion layer 180 may function to convert the blue (B) light into a color of a unit pixel. The phosphor conversion layer 180 may be a red phosphor 181 or a green phosphor 182 constituting an individual pixel.

That is, the red phosphor 181 capable of converting blue light into red (R) light may be laminated on a blue semiconductor light emitting device at a position of a unit pixel of red color, and the green phosphor 182 capable of converting blue light into green (G) light may be laminated on the blue semiconductor light emitting device at a position of a unit pixel of green color. Only the blue semiconductor light emitting device may be used alone in the portion constituting the unit pixel of blue color. In this case, unit pixels of red (R), green (G), and blue (B) may constitute one pixel. More specifically, a phosphor of one color may be laminated along each line of the first electrode 120. Accordingly, one line on the first electrode 120 may be an electrode for controlling one color. That is, red (R), green (G), and blue (B) may be sequentially disposed along the second electrode 140, thereby implementing a unit pixel.

However, embodiments of the present disclosure are not limited thereto. Unit pixels of red (R), green (G), and blue (B) may be implemented by combining the semiconductor light emitting device 150 and the quantum dot (QD) rather than using the phosphor.

Also, a black matrix 191 may be disposed between the phosphor conversion layers to improve contrast. That is, the black matrix 191 may improve contrast of light and darkness.

However, embodiments of the present disclosure are not limited thereto, and anther structure may be applied to implement blue, red, and green colors.

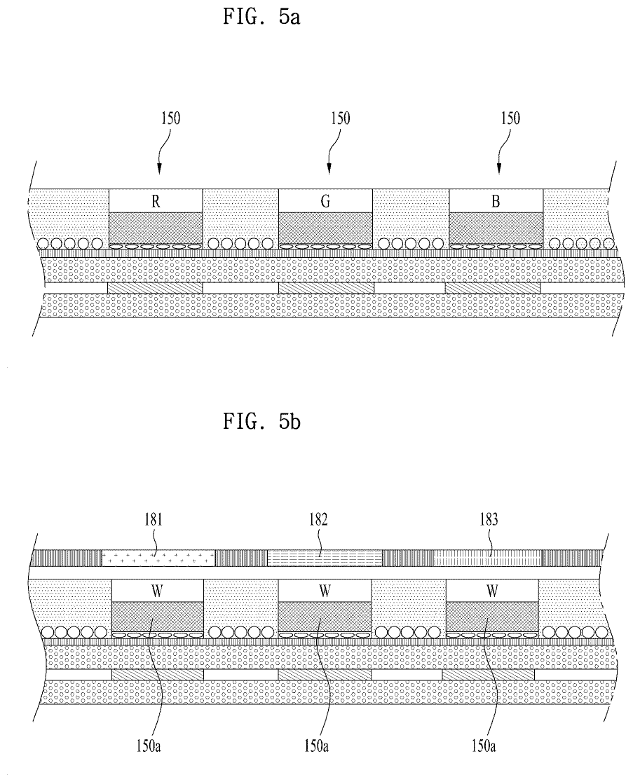

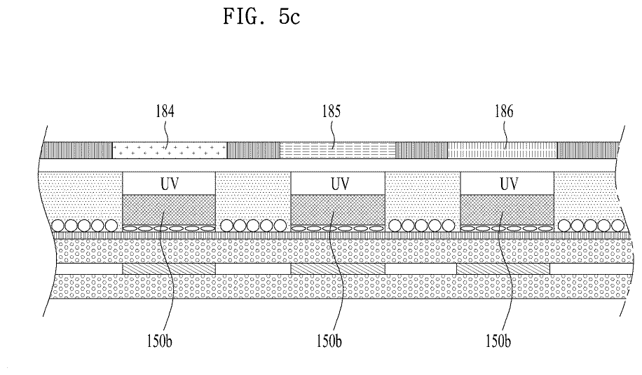

FIGS. 5A to 5C are conceptual views illustrating various examples of implementation of colors in relation to a flip-chip type semiconductor light emitting device.

Referring to FIG. 5A, each semiconductor light emitting device may be implemented as a high-power light emitting device emitting light of various colors including blue by using gallium nitride (GaN) as a main material and adding indium (In) and/or aluminum (Al).

In this case, each semiconductor light emitting device may be a red, green, or blue semiconductor light emitting device to form a unit pixel (sub-pixel). For example, red, green, and blue semiconductor light emitting devices R, G, and B may be alternately disposed, and unit pixels of red, green, and blue may constitute one pixel by the red, green and blue semiconductor light emitting devices. Thereby, a full-color display may be implemented.

Referring to FIG. 5B, the semiconductor light emitting device 150a may include a white light emitting device W having a yellow phosphor conversion layer, which is provided for each device. In this case, in order to form a unit pixel, a red phosphor conversion layer 181, a green phosphor conversion layer 182, and a blue phosphor conversion layer 183 may be disposed on the white light emitting device W. In addition, a unit pixel may be formed using a color filter repeating red, green, and blue on the white light emitting device W.

Referring to FIG. 5C, a red phosphor conversion layer 181, a green phosphor conversion layer 185, and a blue phosphor conversion layer 183 may be provided on a ultraviolet light emitting device. Not only visible light but also ultraviolet (UV) light may be used in the entire region of the semiconductor light emitting device. In an embodiment, UV may be used as an excitation source of the upper phosphor in the semiconductor light emitting device.

Referring back to this example, the semiconductor light emitting device is positioned on the conductive adhesive layer to constitute a unit pixel in the display device. Since the semiconductor light emitting device has excellent luminance, individual unit pixels may be configured despite even when the semiconductor light emitting device has a small size.

Regarding the size of such an individual semiconductor light emitting device, the length of each side of the device may be, for example, 80 m or less, and the device may have a rectangular or square shape. When the semiconductor light emitting device has a rectangular shape, the size thereof may be less than or equal to 20 μm×80 μm.

In addition, even when a square semiconductor light emitting device having a side length of 10 μm is used as a unit pixel, sufficient brightness to form a display device may be obtained.

Therefore, for example, in case of a rectangular pixel having a unit pixel size of 600 μm×300 μm (i.e., one side by the other side), a distance of a semiconductor light emitting device becomes sufficiently long relatively.

Thus, in this case, it is able to implement a flexible display device having high image quality over HD image quality.

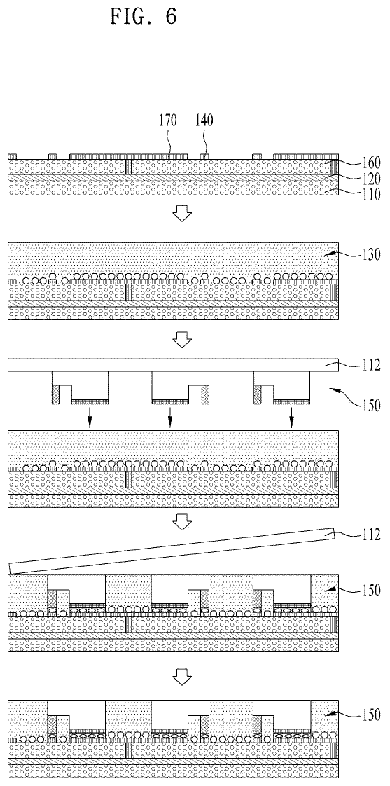

The above-described display device using the semiconductor light emitting device may be prepared by a new fabricating method. Such a fabricating method will be described with reference to FIG. 6 as follows.

FIG. 6 shows cross-sectional views of a method of fabricating a display device using a semiconductor light emitting device according to the present disclosure.

Referring to FIG. 6, first of all, a conductive adhesive layer 130 is formed on an insulating layer 160 located between an auxiliary electrode 170 and a second electrode 140. The insulating layer 160 is tacked on a wiring substrate 110. On the wiring substrate 110, a first electrode 120, the auxiliary electrode 170 and the second electrode 140 are disposed. In this case, the first electrode 120 and the second electrode 140 may be disposed in mutually orthogonal directions, respectively. In order to implement a flexible display device, the wiring substrate 110 and the insulating layer 160 may include glass or polyimide (PI) each.

For example, the conductive adhesive layer 130 may be implemented by an anisotropic conductive film. To this end, an anisotropic conductive film may be coated on the substrate on which the insulating layer 160 is located.

Subsequently, a temporary substrate 112, on which a plurality of semiconductor light emitting devices 150 configuring individual pixels are located to correspond to locations of the auxiliary electrode 170 and the second electrodes 140, is disposed in a manner that the semiconductor light emitting device 150 confronts the auxiliary electrode 170 and the second electrode 140.

In this regard, the temporary 112 substrate 112 is a growing substrate for growing the semiconductor light emitting device 150 and may include a sapphire or silicon substrate.

The semiconductor light emitting device is configured to have a space and size for configuring a display device when formed in unit of wafer, thereby being effectively used for the display device.

Subsequently, the wiring substrate 110 and the temporary substrate 112 are thermally compressed together. By the thermocompression, the wiring substrate 110 and the temporary substrate 112 are bonded together. Owing to the property of an anisotropic conductive film having conductivity by thermocompression, only a portion among the semiconductor light emitting device 150, the auxiliary electrode 170 and the second electrode 140 has conductivity, via which the electrodes and the semiconductor light emitting device 150 may be connected electrically. In this case, the semiconductor light emitting device 150 is inserted into the anisotropic conductive film, by which a partition may be formed between the semiconductor light emitting devices 150.

Then the temporary substrate 112 is removed. For example, the temporary substrate 112 may be removed using Laser Lift-Off (LLO) or Chemical Lift-Off (CLO).

Finally, by removing the temporary substrate 112, the semiconductor light emitting devices 150 exposed externally. If necessary, the wiring substrate 110 to which the semiconductor light emitting devices 150 are coupled may be coated with silicon oxide (SiOx) or the like to form a transparent insulating layer (not shown).

In addition, a step of forming a phosphor layer on one side of the semiconductor light emitting device 150 may be further included. For example, the semiconductor light emitting device 150 may include a blue semiconductor light emitting device emitting Blue (B) light, and a red or green phosphor for converting the blue (B) light into a color of a unit pixel may form a layer on one side of the blue semiconductor light emitting device.

The above-described fabricating method or structure of the display device using the semiconductor light emitting device may be modified into various forms. For example, the above-described display device may employ a vertical semiconductor light emitting device.

Furthermore, a modification or embodiment described in the following may use the same or similar reference numbers for the same or similar configurations of the former example and the former description may apply thereto.

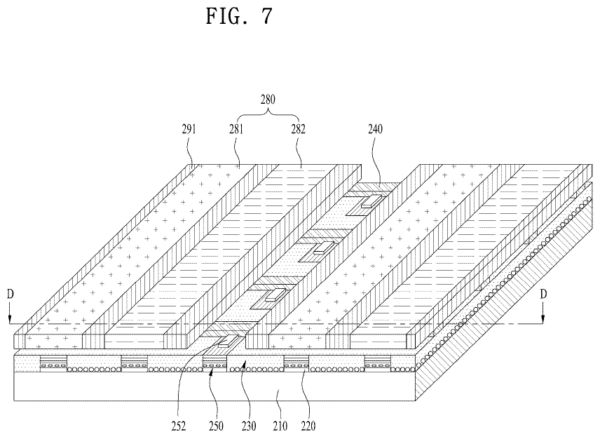

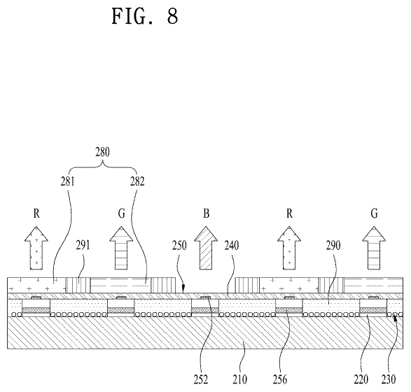

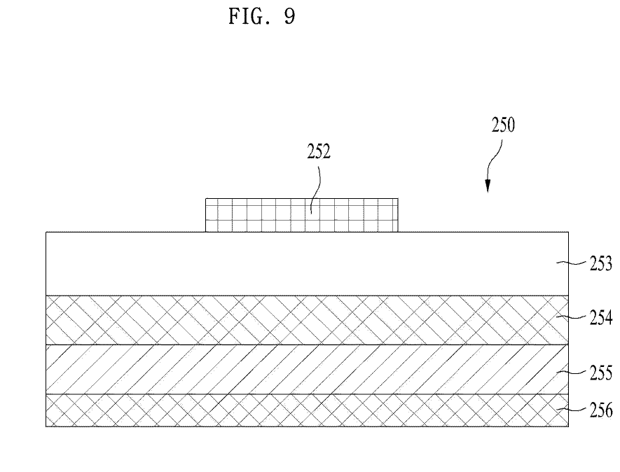

FIG. 7 is a perspective diagram of a display device using a semiconductor light emitting device according to another embodiment of the present disclosure, FIG. 8 is a cross-sectional diagram taken along a cutting line D-D shown in FIG. 8, and FIG. 9 is a conceptual diagram showing a vertical type semiconductor light emitting device shown in FIG. 8.

Referring to the present drawings, a display device may employ a vertical semiconductor light emitting device of a Passive Matrix (PM) type.

The display device includes a substrate 210, a first electrode 220, a conductive adhesive layer 230, a second electrode 240 and at least one semiconductor light emitting device 250.

The substrate 210 is a wiring substrate on which the first electrode 220 is disposed and may contain polyimide (PI) to implement a flexible display device. Besides, the substrate 210 may use any substance that is insulating and flexible.

The first electrode 210 is located on the substrate 210 and may be formed as a bar type electrode that is long in one direction. The first electrode 220 may be configured to play a role as a data electrode.

The conductive adhesive layer 230 is formed on the substrate 210 where the first electrode 220 is located. Like a display device to which a light emitting device of a flip chip type is applied, the conductive adhesive layer 230 may include one of an Anisotropic Conductive Film (ACF), an anisotropic conductive paste, a conductive particle contained solution and the like. Yet, in the present embodiment, a case of implementing the conductive adhesive layer 230 with the anisotropic conductive film is exemplified.

After the conductive adhesive layer has been placed in the state that the first electrode 220 is located on the substrate 210, if the semiconductor light emitting device 250 is connected by applying heat and pressure thereto, the semiconductor light emitting device 250 is electrically connected to the first electrode 220. In doing so, the semiconductor light emitting device 250 is preferably disposed to be located on the first electrode 220.

If heat and pressure is applied to an anisotropic conductive film, as described above, since the anisotropic conductive film has conductivity partially in a thickness direction, the electrical connection is established. Therefore, the anisotropic conductive film is partitioned into a conductive portion and a non-conductive portion.

Furthermore, since the anisotropic conductive film contains an adhesive component, the conductive adhesive layer 230 implements mechanical coupling between the semiconductor light emitting device 250 and the first electrode 220 as well as mechanical connection.

Thus, the semiconductor light emitting device 250 is located on the conductive adhesive layer 230, via which an individual pixel is configured in the display device. As the semiconductor light emitting device 250 has excellent luminance, an individual unit pixel may be configured in small size as well. Regarding a size of the individual semiconductor light emitting device 250, a length of one side may be equal to or smaller than 80 μm for example and the individual semiconductor light emitting device 250 may include a rectangular or square element. For example, the rectangular element may have a size equal to or smaller than 20 μm×80 μm.

The semiconductor light emitting device 250 may have a vertical structure.

Among the vertical type semiconductor light emitting devices, a plurality of second electrodes 240 respectively and electrically connected to the vertical type semiconductor light emitting devices 250 are located in a manner of being disposed in a direction crossing with a length direction of the first electrode 220.

Referring to FIG. 9, the vertical type semiconductor light emitting device 250 includes a p-type electrode 256, a p-type semiconductor layer 255 formed on the p-type electrode 256, an active layer 254 formed on the p-type semiconductor layer 255, an n-type semiconductor layer 253 formed on the active layer 254, and an n-type electrode 252 formed on then-type semiconductor layer 253. In this case, the p-type electrode 256 located on a bottom side may be electrically connected to the first electrode 220 by the conductive adhesive layer 230, and the n-type electrode 252 located on a top side may be electrically connected to a second electrode 240 described later. Since such a vertical type semiconductor light emitting device 250 can dispose the electrodes at top and bottom, it is considerably advantageous in reducing a chip size.

Referring to FIG. 8 again, a phosphor layer 280 may formed on one side of the semiconductor light emitting device 250. For example, the semiconductor light emitting device 250 may include a blue semiconductor light emitting device 251 emitting blue (B) light, and a phosphor layer 280 for converting the blue (B) light into a color of a unit pixel may be provided. In this regard, the phosphor layer 280 may include a red phosphor 281 and a green phosphor 282 configuring an individual pixel.

Namely, at a location of configuring a red unit pixel, the red phosphor 281 capable of converting blue light into red (R) light may be stacked on a blue semiconductor light emitting device. At a location of configuring a green unit pixel, the green phosphor 282 capable of converting blue light into green (G) light may be stacked on the blue semiconductor light emitting device. Moreover, the blue semiconductor light emitting device may be singly usable for a portion that configures a blue unit pixel. In this case, the unit pixels of red (R), green (G) and blue (B) may configure a single pixel.

Yet, the present disclosure is non-limited by the above description. In a display device to which a light emitting device of a flip chip type is applied, as described above, a different structure for implementing blue, red and green may be applicable.

Regarding the present embodiment again, the second electrode 240 is located between the semiconductor light emitting devices 250 and connected to the semiconductor light emitting devices electrically. For example, the semiconductor light emitting devices 250 are disposed in a plurality of columns, and the second electrode 240 may be located between the columns of the semiconductor light emitting devices 250.

Since a distance between the semiconductor light emitting devices 250 configuring the individual pixel is sufficiently long, the second electrode 240 may be located between the semiconductor light emitting devices 250.

The second electrode 240 may be formed as an electrode of a bar type that is long in one direction and disposed in a direction vertical to the first electrode.

In addition, the second electrode 240 and the semiconductor light emitting device 250 may be electrically connected to each other by a connecting electrode protruding from the second electrode 240. Particularly, the connecting electrode may include a n-type electrode of the semiconductor light emitting device 250. For example, the n-type electrode is formed as an ohmic electrode for ohmic contact, and the second electrode covers at least one portion of the ohmic electrode by printing or deposition. Thus, the second electrode 240 and the n-type electrode of the semiconductor light emitting device 250 may be electrically connected to each other.

Referring to FIG. 8 again, the second electrode 240 may be located on the conductive adhesive layer 230. In some cases, a transparent insulating layer (not shown) containing silicon oxide (SiOx) and the like may be formed on the substrate 210 having the semiconductor light emitting device 250 formed thereon. If the second electrode 240 is placed after the transparent insulating layer has been formed, the second electrode 240 is located on the transparent insulating layer. Alternatively, the second electrode 240 may be formed in a manner of being spaced apart from the conductive adhesive layer 230 or the transparent insulating layer.

If a transparent electrode of Indium Tin Oxide (ITO) or the like is sued to place the second electrode 240 on the semiconductor light emitting device 250, there is a problem that ITO substance has poor adhesiveness to an n-type semiconductor layer. Therefore, according to the present disclosure, as the second electrode 240 is placed between the semiconductor light emitting devices 250, it is advantageous in that a transparent electrode of ITO is not used. Thus, light extraction efficiency can be improved using a conductive substance having good adhesiveness to an n-type semiconductor layer as a horizontal electrode without restriction on transparent substance selection.

Referring to FIG. 8 again, a partition 290 may be located between the semiconductor light emitting devices 250. Namely, in order to isolate the semiconductor light emitting device 250 configuring the individual pixel, the partition 290 may be disposed between the vertical type semiconductor light emitting devices 250. In this case, the partition 290 may play a role in separating the individual unit pixels from each other and be formed with the conductive adhesive layer 230 as an integral part. For example, by inserting the semiconductor light emitting device 250 in an anisotropic conductive film, a base member of the anisotropic conductive film may form the partition.

In addition, if the base member of the anisotropic conductive film is black, the partition 290 may have reflective property as well as a contrast ratio may be increased, without a separate block insulator.

For another example, a reflective partition may be separately provided as the partition 190. The partition 290 may include a black or white insulator depending on the purpose of the display device.

In case that the second electrode 240 is located right onto the conductive adhesive layer 230 between the semiconductor light emitting devices 250, the partition 290 may be located between the vertical type semiconductor light emitting device 250 and the second electrode 240 each. Therefore, an individual unit pixel may be configured using the semiconductor light emitting device 250. Since a distance between the semiconductor light emitting devices 250 is sufficiently long, the second electrode 240 can be placed between the semiconductor light emitting devices 250. And, it may bring an effect of implementing a flexible display device having HD image quality.

In addition, as shown in FIG. 8, a black matrix 291 may be disposed between the respective phosphors for the contrast ratio improvement. Namely, the black matrix 291 may improve the contrast between light and shade.

In the display device using the semiconductor light emitting device according to the present disclosure described above, the semiconductor light emitting device is disposed on the wiring substrate in the flip-chip type and used as an individual pixel.

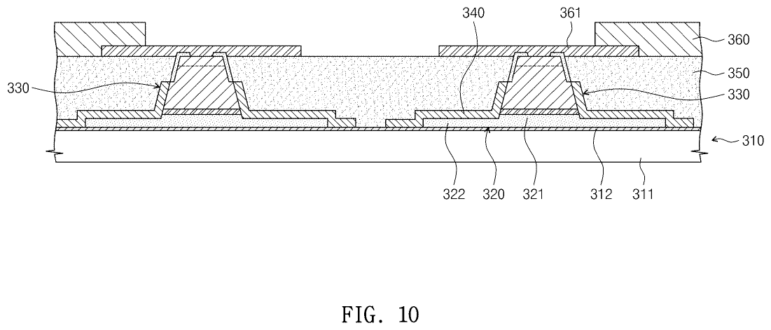

FIG. 10 is a cross-sectional view showing a display device using a semiconductor light emitting device according to an embodiment of the present disclosure. FIG. 11A is a cross-sectional view showing an individual sub-pixel of a display device using a semiconductor light emitting device according to an embodiment of the present disclosure.

Referring to FIGS. 10 and 11A, a display device 300 according to one embodiment of the present disclosure may be constructed as a light emitting device 330 constituting a unit sub-pixel is disposed on a wiring substrate 310 on which a first electrode 312 is disposed.

The wiring substrate 310 may include the first electrode 312 disposed on the substrate 311.

In the wiring substrate 310, multiple first electrodes 312 may be located on the substrate 311. Such a first electrode 312 may be used as a wiring electrode. The first electrode 312 may be positioned separately on the substrate 311. In this regard, the wiring electrode may be used as a data electrode (a pixel electrode) or a scan electrode (a common electrode).

The light emitting devices 330 constituting the three unit sub-pixels may constitute a unit pixel. In this regard, the light emitting device 330 may include a red light emitting device that emits red light, a green light emitting device that emits green light, and a blue light emitting device that emits blue light. Such unit pixels may be repeatedly arranged on the wiring substrate 310.

Although not shown, the first electrode 312 disposed on the wiring substrate 310 may be connected to a TFT layer equipped with a thin film transistor (TFT). the data electrode (the pixel electrode) may be connected to such a TFT layer. A detailed description thereof will be omitted.

A seating layer 320 may be positioned between the wiring substrate 310 and the light emitting device 330. Such a seating layer 320 may form a support structure that supports the light emitting device 330.

The seating layer 320 may support a first surface (e.g., a bottom surface) of the light emitting device 330. The seating layer 320 may include a portion having a greater area size than the first surface.

Referring to FIG. 11A, such a seating layer 320 may include a first portion 321 in contact with the light emitting device 330 and a second portion 322 located beneath the first portion 321 and having a greater area size than the first portion 321. In some cases, a portion having a greater area size may be additionally formed beneath the second portion 322. As such, the seating layer 320 may have a staircase shape of two or more steps.

In one example, such first portion 321 and second portion 322 may be formed to have a gentle slope.

As an exemplary embodiment, the first portion 321 and the second portion 322 may have the staircase shape. For example, an area size of the first portion 321 may be equal to an area size of the bottom surface of the light emitting device 330. Additionally, an area size of the second portion 322 may be larger than the area size of the bottom surface of the light emitting device 330.

For example, the first portion 321 of the seating layer 320 may support the light emitting device 330 by being in contact with a lower side of the light emitting device 330, and the second portion 322 may be connected to the first portion 321 and located downward of the first portion 321. For example, the second portion 322 may be located on the wiring substrate 310. For example, the second portion 322 may be positioned in contact with the wiring substrate 310.

The seating layer 320 may include a cured resin layer. For example, the seating layer 320 may be made of a resin material such as photoresist and then cured. For example, such a seating layer 320 may have an adhesive force to fix the light emitting device 330 during an assembly process of the light emitting device 330, and may then be cured to support the light emitting device 330.

As an exemplary embodiment, at least one of a top surface and the bottom surface of the light emitting device 330 may be circular. For example, the light emitting device 330 may have a cylindrical shape or a truncated cone shape.

Referring to FIG. 11A, the light emitting device 330 may include a first conductive semiconductor layer 331, a second conductive semiconductor layer 332, and a light emitting layer (an active layer) 333 located between the first conductive semiconductor layer 331 and the second conductive semiconductor layer 332.

For example, the first conductive semiconductor layer 331 may be an n-type semiconductor layer. In this regard, the second conductive semiconductor layer 332 may be a p-type semiconductor layer. Such a light emitting device 330 may be a nitride-based semiconductor light emitting device. For example, the light emitting device 330 may be a gallium nitride (GaN)-based semiconductor light emitting device.

The light emitting device 330 may be located at a center of the second portion 322 of the seating layer 320.

To provide vertical selectivity when assembling the light emitting device 330, a lower area size of the light emitting device 330 may be greater than an upper area size. For example, an area size of a side of the light emitting device 330 that is close to the seating layer 320 may be greater than an area size of a side thereof that is far from the seating layer 320.

Additionally, the display device 300 may include a first connection electrode 340 that electrically connects the first electrode 312 with one side of the light emitting device 330. Such a first connection electrode 340 may be made of a metal with high electrical conductivity, such as Al, Mo, Cu, Ag, or Pt.

As an exemplary embodiment, the one side of the light emitting device 330 to which the first connection electrode 340 is connected may be a side surface of the light emitting layer 333 of the light emitting device 330. For example, the first connection electrode 340 may be connected laterally to the surface formed by the light emitting layer 333 of the light emitting device 330. Such a first connection electrode 340 may be electrically connected to a side surface of the first conductive semiconductor layer 331 of the light emitting device 330.

Such a first connection electrode 340 may be formed along the side surface of the light emitting device 330 and an upper side of the seating layer 320. In this regard, the first connection electrode 340 may include a side surface 342 located on the side surface of the light emitting device 330 and a bottom surface 343 located on a top surface of the seating layer 320.

In this regard, because the seating layer 320 has the first portion 321 and the second portion 322, the side surface 342 and the bottom surface 343 of the first connection electrode 340 may be connected to each other with a gentle slope. Therefore, the first connection electrode 340 may be formed to be stably connected without disconnection throughout the entire display.

Referring to FIG. 11A, the first connection electrode 340 may be disposed on both sides of the light emitting device 330. In some cases, the first connection electrode 340 may be disposed to cover the side surface of the light emitting device 330.

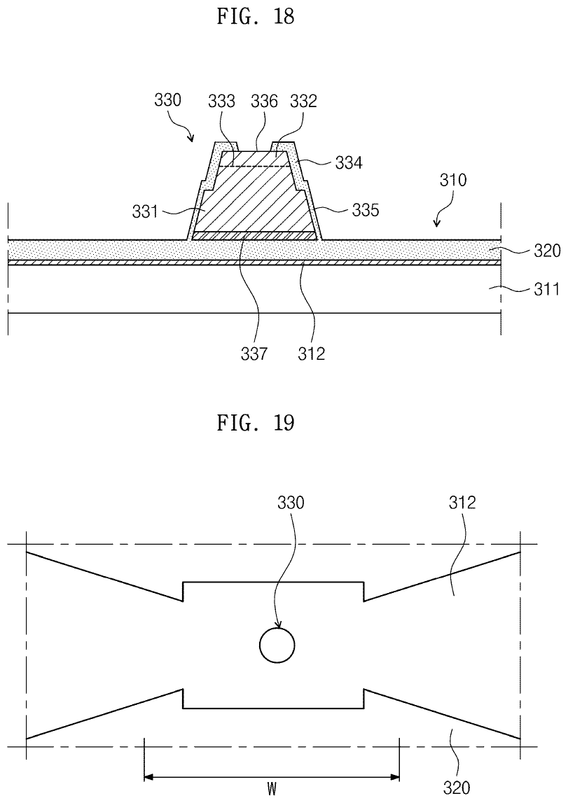

Additionally, such a first connection electrode 340 may be electrically connected to a lower electrode 337 (see FIG. 18) of the light emitting device 330. That is, such a first connection electrode 340 may be connected to a side portion of the lower electrode 337 located at the bottom surface of the light emitting device 330. Such a lower electrode 337 may function as a magnetic layer when assembling the light emitting device 330. To increase an adhesion of at least one of such a magnetic layer 337 and the first connection electrode 340, a metal such as Cr and/or Ti may be added.

The first connection electrode 340 may be located in contact with the seating layer 320. For example, the first connection electrode 340 may be extended along the top surface of the seating layer 320 and connected to the first electrode 312 of the wiring substrate 310.

For example, the first connection electrode 340 may be positioned continuously connected along the first portion 321 and the second portion 322 forming the staircase shape. As such, the first connection electrode 340 may be connected to the first electrode 312 at an end of the second portion 322 of the seating layer 320.

In FIGS. 10 and 11A, a shape of a portion where the first connection electrode 340 is in contact with the first electrode 312 is expressed differently. Such a difference may occur depending on a process of forming the first connection electrode 340.

For example, there may be a vertical level difference 341 where the first connection electrode 340 is connected to the first electrode 312. This may occur depending on a thickness of the seating layer 320. For example, the vertical level difference 341 of the first connection electrode 340 may exist because of a vertical dimension difference of the second portion 322 of the seating layer 320.

On the side surface of the light emitting device 330, a passivation layer 334 may be located outward of the portion to which the first connection electrode 340 is connected. As such, the passivation layer 334 may be located on an outer side of the light emitting device 330, and the first connection electrode 340 may be located beneath the passivation layer 334. Such a passivation layer 334 may protect an outer surface of the light emitting device 330.

A planarization layer 350 may be located on a side of the first connection electrode 340 and the light emitting device 330. The planarization layer 350 may cover the first connection electrode 340 and the light emitting device 330. The planarization layer 350 may have a vertical dimension corresponding to an upper side of the light emitting device 330 or greater.

In this regard, the second conductive semiconductor layer 332 at the upper side of the light emitting device 330 may be exposed. For example, even when the planarization layer 350 has the vertical dimension beyond the upper side of the light emitting device 330, the second conductive semiconductor layer 332 of the light emitting device 330 may be exposed.

Additionally, a second connection electrode 361 located on the planarization layer 350 and electrically connected to the other side of the light emitting device 330 may be located. For example, such a second connection electrode 361 may include a transparent electrode such as an ITO. Accordingly, light emitted from the light emitting device 330 may pass through the second connection electrode 361 and be emitted to the outside.

A shape of the planarization layer 350 is expressed differently in FIGS. 10 and 11A. As such, the shape of the planarization layer 350 may change depending on the case.

Referring to FIG. 10, a second electrode 360 connected to the second connection electrode 361 may be disposed.

As mentioned above, the first electrode 312 and the second electrode 360 may be used as the wiring electrodes. For example, the first electrode 312 may function as the data electrode (the pixel electrode), and the second electrode 360 may function as the scan electrode (the common electrode).

Referring to FIG. 10, the second connection electrode 361 may be partially located on the light emitting device 330. In some cases, such second connection electrodes 361 may be connected to each other by the second electrode 360.

FIG. 11B is a cross-sectional view showing an individual sub-pixel of a display device using a semiconductor light emitting device according to another embodiment of the present disclosure.

Hereinafter, the present embodiment will be described focusing on differences from FIG. 11A.

Referring to FIG. 11B, the seating layer 320 may support the first surface (e.g., the bottom surface) of the light emitting device 330. The seating layer 320 may include the portion having the greater area size than the first surface.

Referring to FIG. 11B, the seating layer 320 may include the first portion 321 in contact with the light emitting device 330, the second portion 322 located below the first portion 321 and having the greater area size than the first portion 321, and a third portion 323 that connects the first portion 321 and the second portion 322 to each other with the gentle slope. In some cases, a fourth portion having a greater area size may be additionally formed under the second portion 322 (not shown). As such, the seating layer 320 may have the staircase shape of the two or more steps.

As such, the first portion 321 and the second portion 322 may be connected to each other via the third portion 323 and may be formed to have the gentle slope.

For example, the area size of the first portion 321 may be equal to the area size of the bottom surface of the light emitting device 330. Additionally, the area size of the second portion 322 may be greater than the area size of the bottom surface of the light emitting device 330.

For example, the first portion 321 of the seating layer 320 may support the light emitting device 330 by being in contact with the lower side of the light emitting device 330, and the second portion 322 may be connected to the first portion 321 and located below the first portion 321. For example, the second portion 322 may be located on the wiring substrate 310. For example, the second portion 322 may be positioned in contact with the wiring substrate 310.

The seating layer 320 may include the cured resin layer. For example, the seating layer 320 may be made of the resin material such as the photoresist and then cured. For example, such a seating layer 320 may have the adhesive force to fix the light emitting device 330 during the assembly process of the light emitting device 330, and may then be cured to support the light emitting device 330.

The display device 300 may include the first connection electrode 340 that electrically connects the first electrode 312 with the one side of the light emitting device 330. Such a first connection electrode 340 may be made of the metal with the high electrical conductivity, such as Al, Mo, Cu, Ag, or Pt.

As the exemplary embodiment, the one side of the light emitting device 330 to which the first connection electrode 340 is connected may be the side surface of the light emitting layer 333 of the light emitting device 330. For example, the first connection electrode 340 may be connected laterally to the surface formed by the light emitting layer 333 of the light emitting device 330. Such a first connection electrode 340 may be electrically connected to the side surface of the first conductive semiconductor layer 331 of the light emitting device 330.

Such a first connection electrode 340 may be formed along the side surface of the light emitting device 330 and the upper side of the seating layer 320. In this regard, the first connection electrode 340 may include the side surface 342 located on the side surface of the light emitting device 330 and the bottom surface 343 located on the top surface of the seating layer 320.

In this regard, because the seating layer 320 has the first portion 321, the second portion 322, and the third portion 323, the side surface 342 and the bottom surface 343 of the first connection electrode 340 may be connected to each other with the gentle slope. Therefore, the first connection electrode 340 may be formed to be stably connected without the disconnection throughout the entire display.

Other components not described may be the same as those in the embodiment described with reference to FIG. 11A.

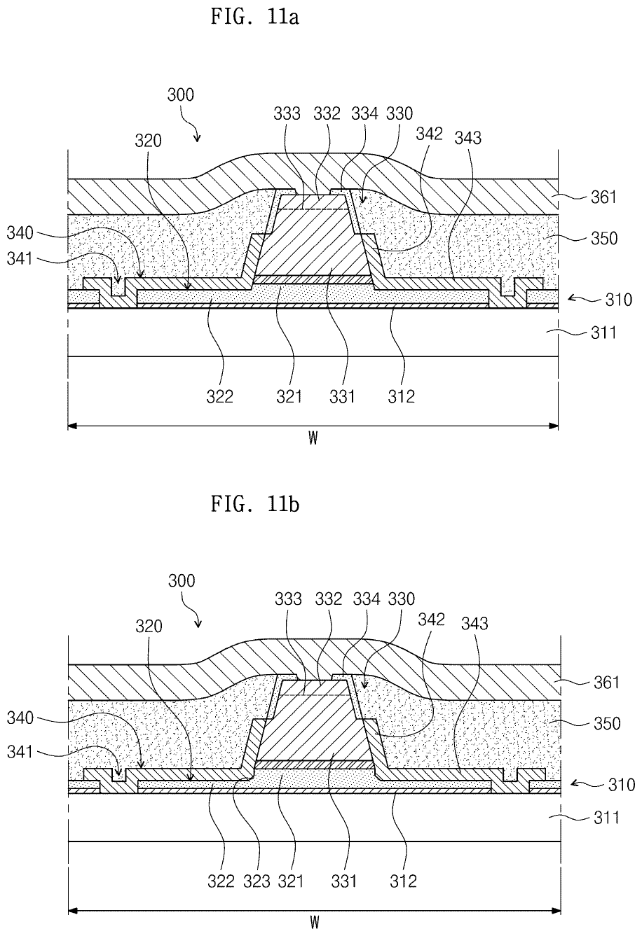

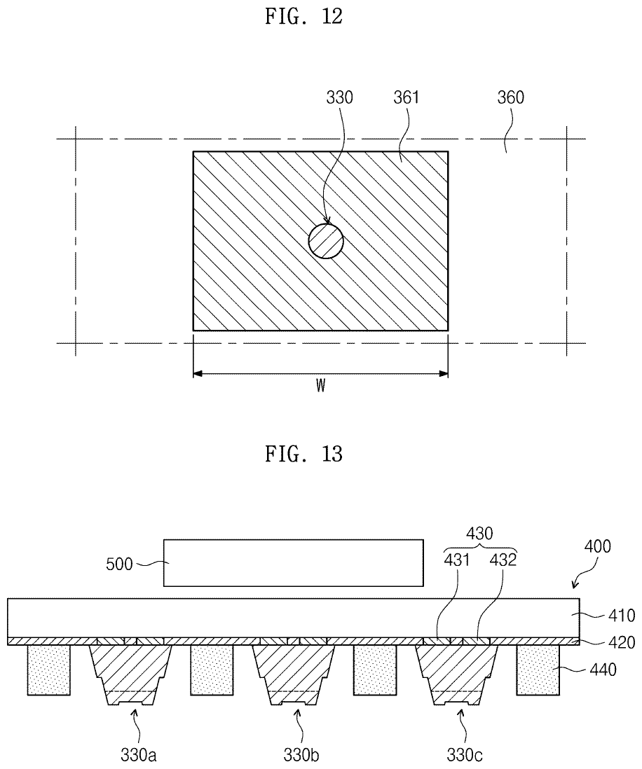

FIG. 12 is a plan view showing an individual sub-pixel of a display device using a semiconductor light emitting device according to an embodiment of the present disclosure.

FIG. 12 shows a top view of each sub-pixel area. In FIG. 12, a width W of the sub-pixel area shown in FIGS. 11A and 11B is shown correspondingly. In FIG. 12, shapes of the second electrode 360, the second connection electrode 361, and the light emitting device 330 are shown.

FIGS. 13 to 30 are cross-sectional views showing a process of manufacturing a display device using a semiconductor light emitting device according to an embodiment of the present disclosure.

Hereinafter, with reference to FIGS. 13 to 30, the process for manufacturing the display device using the semiconductor light emitting device according to an embodiment of the present disclosure will be described step by step.

First, with reference to FIGS. 13 to 17, a process of assembling the light emitting device 330 onto the wiring substrate 310 will be briefly described. In this regard, a shape of the wiring substrate 310 may be expressed differently from the shape of the wiring substrate 310 described above.

Referring to FIG. 13, light emitting devices 330a, 330b, and 330c may be assembled onto an assembling substrate 400.

The assembling substrate 400 may include an assembling electrode 431, 432; 430 and an insulating layer 420 on a base substrate 410. For example, a partition wall 440 that defines an assembly space where the light emitting devices 330a, 330b, and 330c are assembled may be disposed on the insulating layer 420.

As such, the light emitting devices 330a, 330b, and 330c may be assembled onto the assembling substrate 400 using a magnet 500. In this regard, as mentioned above, the light emitting devices 330a, 330b, and 330c may include the magnetic layer 337 (see FIG. 18).

For example, the assembly process of such light emitting devices 330a, 330b, and 330c may be performed in a fluid.

As mentioned above, to provide vertical selectivity of the light emitting devices 330a, 330b, and 330c, it may be advantageous for a lower contact area size to be greater than an upper contact area size. To this end, for example, the contact area size may be adjusted via patterning and/or etching processes of passivation layers of the light emitting devices 330a, 330b, and 330c. Alternatively, as another example, the upper second conductive semiconductor layer 332 may be partially etched to create the difference in the upper and lower contact area sizes.

In this regard, the light emitting devices 330a, 330b, and 330c may include the red light emitting device 330a, the green light emitting device 330b, and the blue light emitting device 330c. Although the three light emitting devices are shown in FIG. 13 and the drawings below, more light emitting devices 330a, 330b, and 330c may be self-assembled using the magnet 500.

The light emitting devices 330a, 330b, and 330c assembled onto the assembling substrate 400 using the magnet 500 may be fixed by a dielectrophoresis (DEP) force as an electric field is applied to the assembly electrode 430.

Referring to FIG. 14, the assembled light emitting devices 330a, 330b, and 330c may be attached to a temporary substrate 600 to be transferred onto the wiring substrate 310. Such a temporary substrate 600 may be a type of stamp.

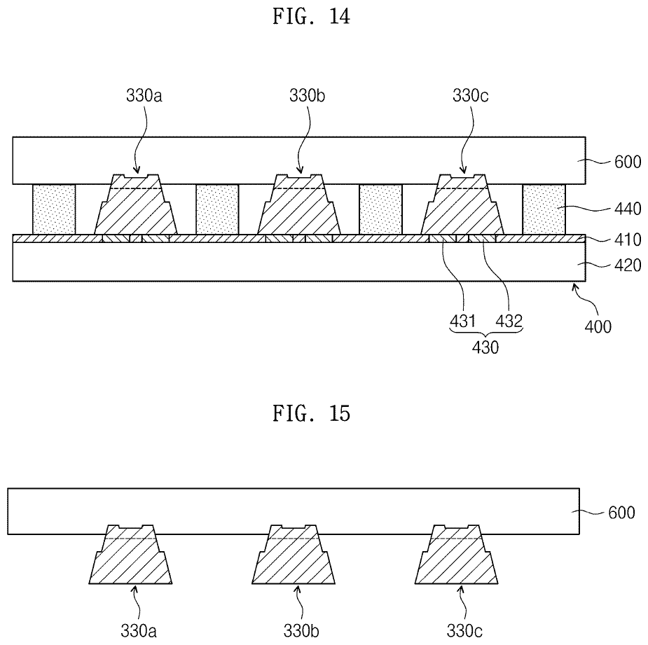

Referring to FIG. 15, the light emitting devices 330a, 330b, and 330c may be removed from the assembling substrate 400 and transferred onto the temporary substrate 600.

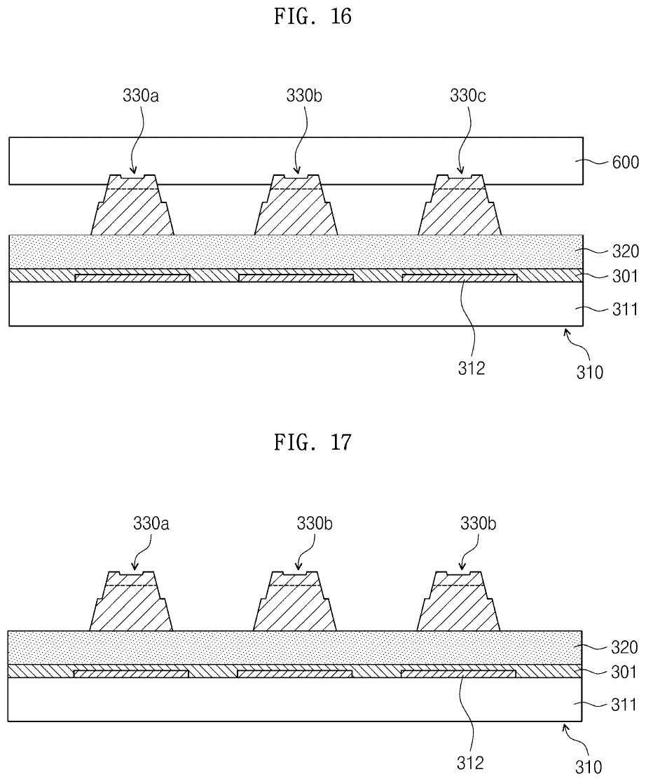

Next, referring to FIG. 16, the light emitting devices 330a, 330b, and 330c may be moved to the wiring substrate 310 for lighting. In this regard, an adhesive layer 320 is located on the wiring substrate 310, so that the light emitting devices 330a, 330b, and 330c may be seated on the adhesive layer 320. Such an adhesive layer 320 may be later cured to be formed as the seating layer 320 described above.

Referring to FIG. 17, the temporary substrate 600 may be removed, and the light emitting devices 330a, 330b, and 330c may be transferred onto the wiring substrate 310.

Hereinafter, with reference to FIGS. 18 to 30, a process of manufacturing the display device 300 will be described step by step.

FIG. 18 shows a state in which the light emitting device 330 is transferred onto the wiring substrate 310. Hereinafter, the process of manufacturing the display device 300 by manufacturing the one light emitting device 330 as the unit sub-pixel will be described.

Referring to FIG. 18, a process of seating the light emitting device 330 on the wiring substrate 310 equipped with the adhesive layer 320 and the first electrode 312 may be performed such that the first surface of the light emitting device 330 is in contact with the adhesive layer 320. FIG. 19 is a top view showing the state shown in FIG. 18.

In this regard, the first surface of the light emitting device 330 may be the bottom surface where the magnetic layer or the lower electrode 337 of the light emitting device 330 is located.

For example, when forming the magnetic layer 337 on a rear surface of the light emitting device 330 to increase light emitting efficiency, the magnetic layer 337 may be deposited on the light emitting device 330 before the assembly of the light emitting device 330. In some cases, such a magnetic layer 337 may be used as an electrode.

The light emitting device 330 may include passivation layers 334 and 335. In this regard, the passivation layer 334 located on an upper side may be thicker than the passivation layer 335 located on a lower side.

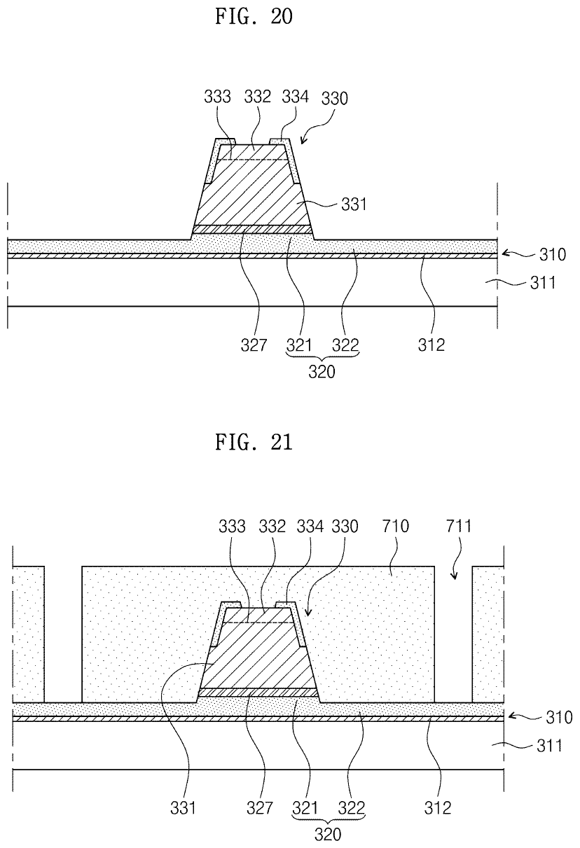

Thereafter, referring to FIG. 20, the wiring substrate 310 on which the light emitting device 330 is mounted may be etched. In such process, contaminants on top of the wiring substrate 310 may be removed. For example, in such a process, a top surface 336 of the light emitting device 330 may be exposed.

In one example, the passivation layer 335 located on the lower side may be removed via the etching process, exposing the side surface of the light emitting device 330.

As such, the passivation layer covering the top surface 336 of the light emitting device 330 may be removed in the etching process, thereby preventing an occurrence of a short circuit in the light emitting device 330 without a separate post-process.

In addition, because there is no need for an additional process margin to open the top surface 336 of the light emitting device 330, chip miniaturization may be achieved, and it may also be advantageous for a wiring process that may occur after chip manufacturing in terms of wiring precision.

Additionally, a portion of the adhesive layer 320 may be etched and removed such that the adhesive layer 320 includes the first portion 321 in contact with the light emitting device 330 and the second portion 322 located beneath the first portion 321. Such an adhesive layer 320 may be the same component as the seating layer 320 described above. As such, the process of etching the adhesive layer 320 in a depth direction of the wiring substrate 310 may be performed.

In one example, by adjusting the etching process step by step, the adhesive layer 320 may be etched to include the first portion 321, the second portion 322 located below the first portion 321, and the third portion 323 that connects the first portion 321 and the second portion 322 to each other with the gentle slope described above with reference to FIG. 11B.

Next, referring to FIG. 21, a photo resist (PR) 710 may be coated and patterned to define a via to connect the first connection electrode 340 and the first electrode 312 to each other.

In this regard, a through portion 711 may be formed in a portion of the photoresist 710 where the via is to be defined.

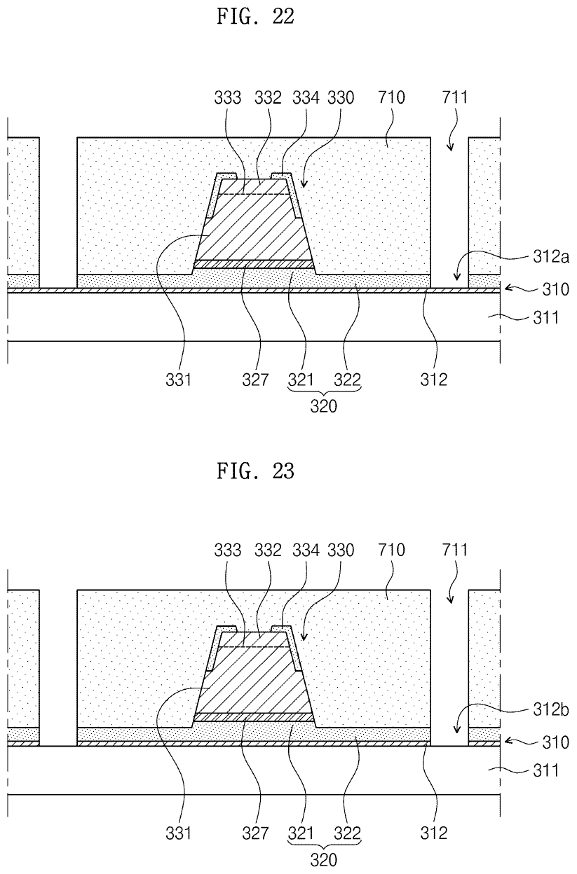

Referring to FIG. 22, a via 312a may be defined via the etching using such a through portion 711 to expose a portion of the first electrode 312.

Referring to FIG. 23, for example, a portion of the first electrode 312 may be removed to connect the first connection electrode 340 and the first electrode 312 to each other. For example, when the first electrode 312 is used as the data electrode, an exposed portion 312b with a deeper shape may be defined and the first electrodes 312 may be separated from each other in the respective sub-pixel areas.

As an exemplary embodiment, forming the first connection electrode 340 may include etching the portion of the adhesive layer 320 to open the portion of the first connection electrode 340 to define the exposed portion 312b.

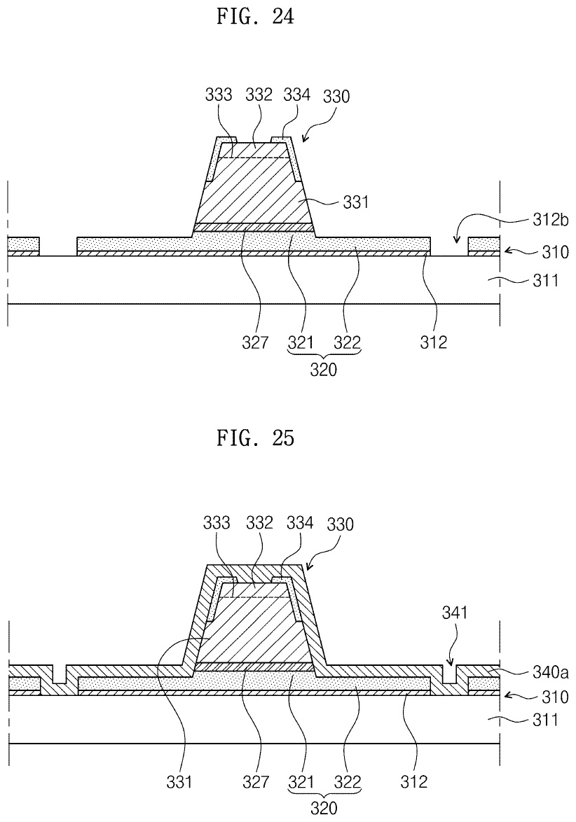

Thereafter, a shape as shown in FIG. 24 may be achieved when removing the photo resist 710.

Next, the process of forming the first connection electrode 340 that connects the one side of the light emitting device 330 to the first electrode 312 may be performed. To this end, a metal layer 340a may be deposited on the side surface and the top surface of the light emitting device 330. For example, as a metal layer material, the metal with the high electrical conductivity such as Al, Mo, Cu, Ag, or Pt may be used. Additionally, as an example, a metal such as Cr and Ti may be used to increase an adhesion of a magnetic layer 327 and the metal layer 340a.

Such a first connection electrode 340 may be formed stably without the disconnection with the gentle slope along the side surface of the light emitting device 330 and the adhesive layer 320.

For example, in the case of the red light emitting device, Au and AuBe may be formed and heat treated to form an ohmic metal, and then the magnetic layer 327 and the metal layer 340a may be formed.

Referring to FIG. 25, the vertical level difference 341 may be formed in a portion where the metal layer 340a for the first connection electrode 340 is connected to the first electrode 312.

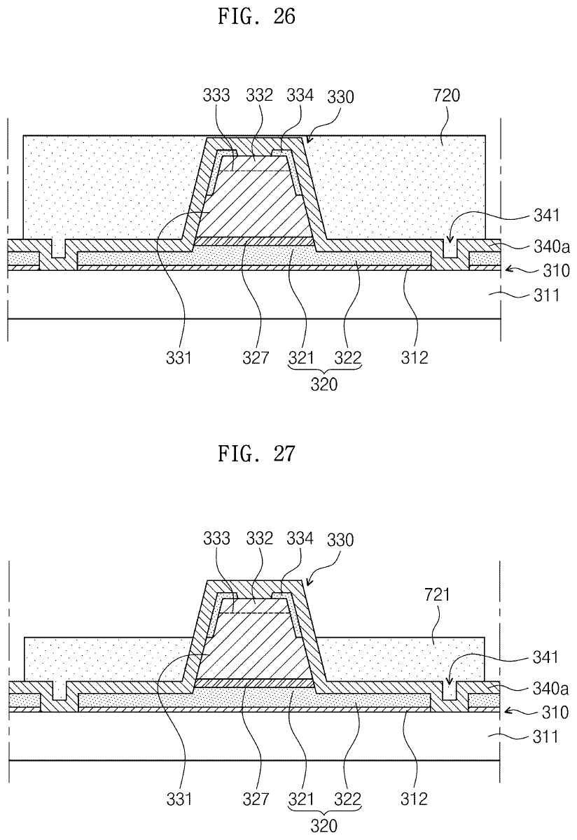

Next, referring to FIG. 26, a photo resist 720 may be formed to pattern the metal layer 340a.

Thereafter, referring to FIG. 27, the photo resist 720 may be patterned to etch the metal layer 340a located on the light emitting device 330. As such, the patterned photo resist 721 may open the top of the light emitting device 330.

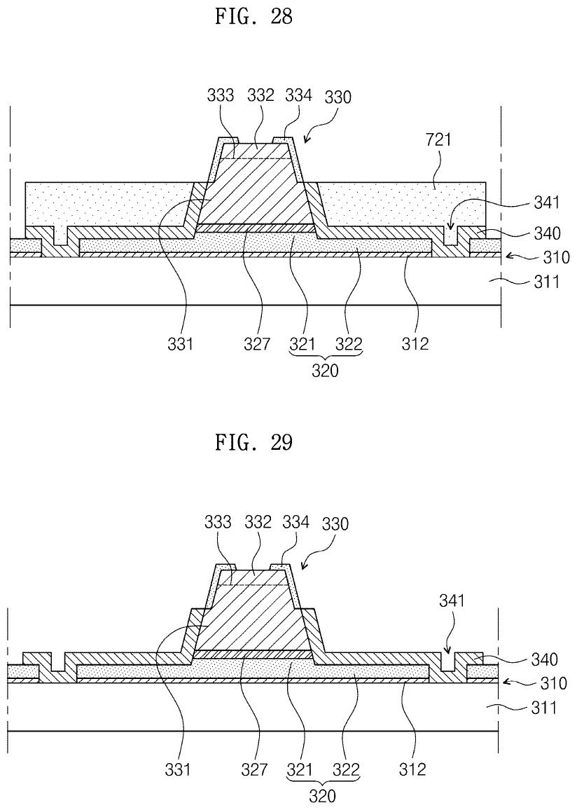

Referring to FIG. 28, the top of the light emitting device 330 may be opened by etching the metal layer 340a. Accordingly, the first connection electrode 340 that connects a portion of the side surface of the light emitting device 330 to the first electrode 312 may be formed.

A sputtering device may be used in the process of forming the metal layer 340a for forming the first connection electrode 340 on the light emitting device 330 having a circular shape.

In one example, metal may be formed on the bottom surface and the side surface of the light emitting device 330 before the assembly. As such, when the metal is formed on the bottom surface and the side surface of the light emitting device 330 and then the light emitting devices 330 are dispersed in the fluid and assembled, an electrode is formed on the bottom surface of the light emitting device 330, and the electric field acts strongly, thereby stably assembling the light emitting device 330 in an assembly hole and improving an assembly rate. Additionally, when the light emitting device 330 is connected to the first connection electrode 340 after being assembled, electrical connection is improved by the metal formed on the light emitting device 330, so that lighting efficiency and lighting uniformity may be improved.

The passivation layer 334 may be located on top of the light emitting device 330 to which the first connection electrode 340 is connected.

Thereafter, when the patterned photo resist 721 is removed, a state shown in FIG. 29 may be achieved.

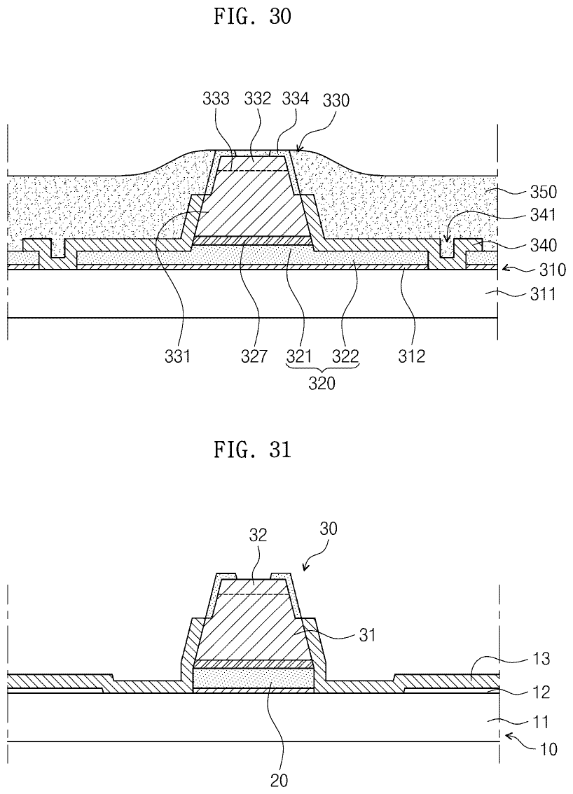

Referring to FIG. 30, the planarization layer 350 that fills up to the top of the light emitting device 330 may be formed. Such a planarization layer 350 may cover the light emitting device 330 and the first connection electrode 340.

Thereafter, a process of forming the second connection electrode 361 that is electrically connected to the other side of the light emitting device 330 on the planarization layer 350 may be performed. As such, when the second connection electrode 361 is formed, the state as shown in FIG. 11A may be achieved. Additionally, herein, by forming the second electrode 360, the display device 300 as shown in FIG. 10 may be manufactured.

FIG. 31 is a cross-sectional view showing a display device using a semiconductor light emitting device according to a comparative example.

Referring to FIG. 31, an example in which a wiring substrate 10 has a light emitting device 30 and a first electrode 12 located on a substrate 11, and the light emitting device 30 and the first electrode 12 are connected to each other by a connection electrode 13 is shown.

In this regard, the light emitting device 30 includes a first conductive semiconductor layer 31 and a second conductive semiconductor layer 32, and a seating layer 20 is disposed under the first conductive semiconductor layer 31.

In this regard, the seating layer 20 has the same area size as a bottom surface of the light emitting device 30. That is, the seating layer 20 may have substantially the same area size as the first conductive semiconductor layer 31.

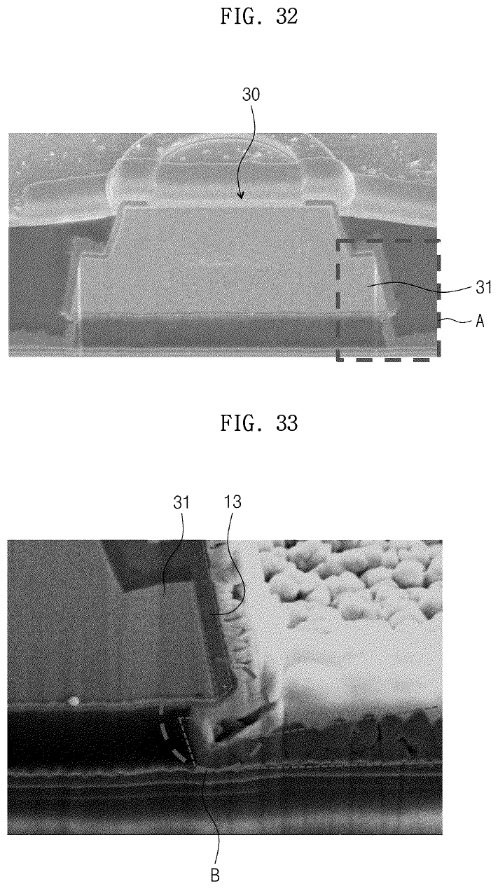

FIG. 32 is a photograph showing a portion of a display device using a semiconductor light emitting device according to a comparative example. FIG. 33 is an enlarged photograph of a portion A in FIG. 32.

Referring to FIG. 32, an appearance of the light emitting device 30 is mainly shown.

Referring to FIG. 33, an undercut occurs at a portion where the seating layer 20 and the first conductive semiconductor layer 31 of the light emitting device 30 are connected to each other, resulting in disconnection of the connection electrode 13 (a portion B).

After the light emitting device 30 is mounted on an adhesive layer constituting the seating layer 20, the undercut may occur during a manufacturing process or a patterning process. Therefore, when forming the connection electrode 13, the connection electrode 13 may be disconnected at such an undercut portion. Ultimately, the light emitting device 30 may not be electrically connected to the wiring substrate 10.

When forming the connection electrode 13, when a thickness of the connection electrode 13 is great, it is difficult to adjust an ashing process for patterning the connection electrode 13. Then, a metal on a side surface of the light emitting device 30 may be etched, causing the connection electrode 13 to be disconnected.

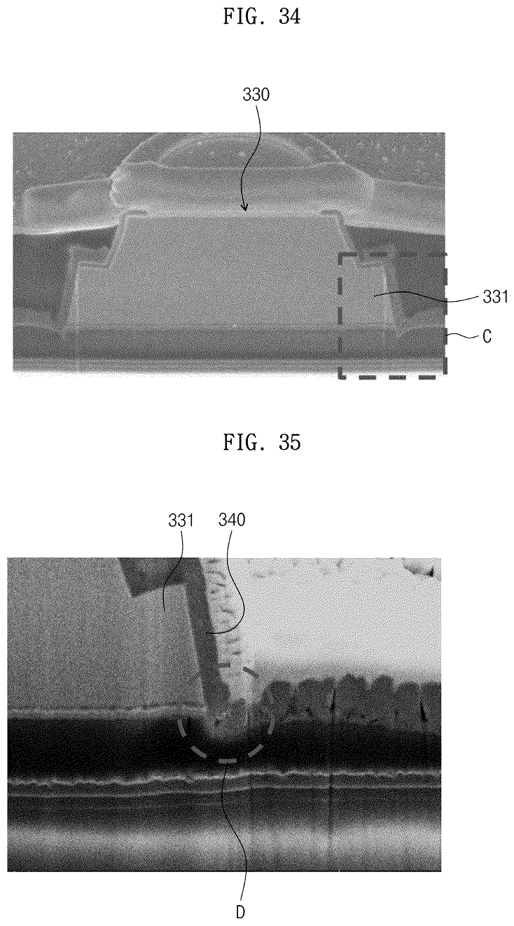

FIG. 34 is a photograph showing a portion of a display device using a semiconductor light emitting device according to an embodiment of the present disclosure. FIG. 35 is an enlarged photograph of a portion C in FIG. 34.

Referring to FIG. 34, a state shown in FIG. 34 corresponds to the state described above with reference to FIGS. 10 and 11. Additionally, FIGS. 34 and 35 show states corresponding to the manufacturing process described above.

Referring to FIG. 35, it may be seen that the first connection electrode 340 is connected without being disconnected at the portion where the seating layer 320 and the first conductive semiconductor layer 331 of the light emitting device 330 are connected to each other (a portion D).

As such, when the pattern of the seating layer 320 is formed to form the first connection electrode 340, the first connection electrode 340 is well connected to and located between the light emitting device 330 and the first electrode 312, thereby reducing a defect rate in a lighting process.

According to the embodiment of the present disclosure, the step of the seating layer 320 may be reduced step by step, so that the first connection electrode 340 may be stably formed, thereby reducing the thickness of the metal to be deposited. This may reduce a metal etching time.

In one example, when the photo resist is formed with the shape thereof controlled in the photo resist patterning process, a shape of the seating layer (the adhesive layer) 320 is created based on the shape of the photo resist. In this regard, when the slope of the seating layer 320 is formed gently, the first connection electrode 340 may be formed along the slope and may be formed stably without being disconnected.

The features, the structures, the effects, and the like described in the embodiments above are included in at least one embodiment of the present disclosure and are not necessarily limited to only one embodiment. Furthermore, the features, the structures, the effects, and the like illustrated in each embodiment may be combined or modified for other embodiments by a person with ordinary knowledge in the field to which the embodiments belong. Therefore, contents related to such combinations and modifications should be interpreted as being included within the scope of the present disclosure.

In addition, although the above description focuses on the embodiment, this is only an example and does not limit the present disclosure. Those skilled in the art in the field to which the present disclosure belongs will recognize that various modifications and applications not illustrated above are possible without departing from the essential characteristics of the present embodiment. For example, each component specifically shown in the embodiment may be modified. In addition, the differences related to such modifications and applications should be construed as being included within the scope of the present disclosure as defined in the attached claims.

What is claimed is:

1. A display device using a semiconductor light emitting device, the display device comprising:
a wiring substrate with a first electrode disposed thereon;
the light emitting device disposed on the wiring substrate to constitute a unit sub-pixel;
a seating layer located between the wiring substrate and the light emitting device, wherein the seating layer includes a first portion in contact with the light emitting device and a second portion located under the first portion and having an area size greater than an area size of the first portion;
a first connection electrode electrically connecting the first electrode to one side of the light emitting device corresponding to a shape of the seating layer;
a planarization layer covering the light emitting device and the first connection electrode; and
a second connection electrode located on the planarization layer and electrically connected to the other side of the light emitting device.

2. The display device of claim 1, wherein the first portion and the second portion form a staircase shape.

3. The display device of claim 1, wherein the area size of the first portion is equal to an area size of a bottom surface of the light emitting device.

4. The display device of claim 1, wherein the seating layer further includes a third portion connecting the first portion and the second portion to each other with a gentle slope.

5. The display device of claim 1, wherein the light emitting device is located on a center of the second portion.

6. The display device of claim 1, wherein the one side of the light emitting device connected with the first connection electrode is a side surface of a light emitting layer of the light emitting device.

7. The display device of claim 6, wherein the first connection electrode connects the first electrode with a lower portion of the side surface of the light emitting layer of the light emitting device.

8. The display device of claim 1, wherein a passivation layer is located on an outer side of the light emitting device, and the first connection electrode is located beneath the passivation layer.

9. The display device of claim 1, wherein the first connection electrode is connected to the first electrode at an end of the second portion of the seating layer.

10. The display device of claim 1, wherein the first connection electrode is connected to a lower electrode of the light emitting device.

11. The display device of claim 1, wherein the second connection electrode includes a transparent electrode.

12. The display device of claim 1, further comprising a second electrode connected to the second connection electrode.

13. The display device of claim 1, wherein the seating layer includes a cured resin layer.

14. A display device using a semiconductor light emitting device, the display device comprising:
a wiring substrate with a first electrode disposed thereon;
the light emitting device disposed on the wiring substrate;
a seating layer located between the wiring substrate and the light emitting device, supporting a first surface of the light emitting device, and having an area size greater than an area size of the first surface;
a first connection electrode electrically connecting the first electrode to one side of the light emitting device;
a planarization layer covering the light emitting device and the first connection electrode; and
a second connection electrode located on the planarization layer and electrically connected to the other side of the light emitting device.

15. The display device of claim 14, wherein the seating layer includes a first portion supporting the first surface and a second portion located under the first portion and having an area size greater than an area size of the first portion.

16. The display device of claim 15, wherein the seating layer further includes a third portion connecting the first portion and the second portion to each other with a gentle slope.

17. The display device of claim 15, wherein the area size of the first portion is equal to an area size of a bottom surface of the light emitting device.

18. A method for manufacturing a display device using a semiconductor light emitting device, the method comprising:
seating the light emitting device on a wiring substrate having an adhesive layer and a first electrode such that a first surface of the light emitting device is in contact with the adhesive layer;
etching the adhesive layer in a depth direction of the wiring substrate;
forming a first connection electrode connecting one side of the light emitting device to the first electrode along a top surface of the adhesive layer;
forming a planarization layer covering the light emitting device and the first connection electrode; and
forming a second connection electrode electrically connected to the other side of the light emitting device on the planarization layer.

19. The method of claim 18, wherein the etching of the adhesive layer includes:
etching the adhesive layer such that the adhesive layer includes a first portion in contact with the light emitting device and a second portion located under the first portion and having an area size greater than an area size of the first portion.

20. The method of claim 18, wherein the forming of the first connection electrode includes:
etching a portion of the adhesive layer to open a portion of the first connection electrode to define an exposed portion.
